(19) United States
(12) Patent Application Publication
(10) Pub. No.: US 2026/0245515 A1
(43) Pub. Date: Aug. 20, 2026

(54) DISPLAY SUBSTRATE AND MANUFACTURE METHOD THEREOF, DISPLAY APPARATUS

(71) Applicant: BOE TECHNOLOGY GROUP CO., LTD., Beijing (CN)

(72) Inventors: Wei YANG, Beijing (CN); Ce NING, Beijing (CN); Wei LIU, Beijing (CN)

(73) Assignee: BOE TECHNOLOGY GROUP CO., LTD., Beijing (CN)

(21) Appl. No.: 18/995,082

(22) PCT Filed: Aug. 31, 2023
(86) PCT No.: PCT/CN2023/116298

§ 371 Date: Jan. 15, 2025

(51) Int. Cl. G09G 3/3233; G09G 3/00; G09G 3/20; H10K 59/121

(52) U.S. Cl. CPC G09G 3/3233; G09G 3/035; G09G 3/2074; H10K 59/1213; G09G 2300/0408; G09G 2300/0819; G09G 2300/0842; G09G 2300/0861; G09G 2320/0233; G09G 2330/023

(57) ABSTRACT

A display substrate and a manufacture method thereof, a display apparatus are provided. The display substrate includes a sub-pixel, the sub-pixel includes a pixel circuit, the pixel circuit includes a light-emitting device and a driving transistor, the driving transistor is configured to control a magnitude of a driving current flowing through the light-emitting device according to a data signal; the pixel circuit further includes a data transistor, the data transistor is configured to write the data signal into a first electrode of the driving transistor in response to a data driving signal; a material of an active layer of the driving transistor is a metal oxide semiconductor material, and a material of an active layer of the data transistor includes a silicon semiconductor material.

### TECHNICAL FIELD

Embodiments of the present disclosure provide a display substrate and a manufacture method thereof, a display apparatus.

### BACKGROUND

The LTPO display substrate integrates oxide transistors (Oxide TFT) and low-temperature polycrystalline silicon transistors (LTPS TFT), which have the advantage of low-frequency driving and can reduce the power consumption of display products, and has been increasingly applied in organic light-emitting diode (OLED) display substrates, such as flexible active organic light-emitting diode (AMOLED) display substrates for mobile display products.

### SUMMARY

At least one embodiment of the present disclosure provides a display substrate, the display substrate includes a sub-pixel, the sub-pixel includes a pixel circuit, the pixel circuit includes a light-emitting device and a driving transistor, the driving transistor is configured to control a magnitude of a driving current flowing through the light-emitting device according to a data signal; the pixel circuit further includes a data transistor, the data transistor is configured to write the data signal into a first electrode of the driving transistor in response to a data driving signal; a material of an active layer of the driving transistor includes a metal oxide semiconductor material, and a material of an active layer of the data transistor includes a silicon semiconductor material.

At least one embodiment of the present disclosure provides a display substrate, the display substrate includes a sub-pixel, the sub-pixel includes a pixel circuit, the pixel circuit includes a light-emitting device and a driving transistor, the driving transistor is configured to control a magnitude of a driving current flowing through the light-emitting device according to a data signal; the display substrate further includes a base substrate, and the pixel circuit is on a main surface of the base substrate; the pixel circuit further includes a storage capacitor, a first electrode of the storage capacitor is electrically connected to a gate electrode of the driving transistor, and a second electrode of the storage capacitor is electrically connected to a first power voltage terminal to receive a first power voltage; the gate electrode of the driving transistor includes a bottom gate, in a direction perpendicular to the main surface of the base substrate, the bottom gate is on a side of the active layer of the driving transistor close to the base substrate; the first electrode of the storage capacitor, the second electrode of the storage capacitor, and the bottom gate of the driving transistor are in different layers from each other, and both the first electrode of the storage capacitor and the second electrode of the storage capacitor are on a side of the active layer of the driving transistor away from the base substrate.

At least one embodiment of the present disclosure provides a display substrate, the display substrate includes a sub-pixel, the sub-pixel includes a pixel circuit, the pixel circuit includes a light-emitting device and a driving transistor, the driving transistor is configured to control a magnitude of a driving current flowing through the light-emitting device according to a data signal; the display substrate further includes a base substrate, and the pixel circuit is on a main surface of the base substrate; the pixel circuit further includes a storage capacitor, a first electrode of the storage capacitor is electrically connected to a gate electrode of the driving transistor, and a second electrode of the storage capacitor is electrically connected to a first power voltage terminal to receive a first power voltage; an orthographic projection of the storage capacitor on the main surface of the base substrate at least partially overlaps with an orthographic projection of the driving transistor on the main surface of the base substrate.

For example, in the display substrate provided by at least one embodiment of the present disclosure, the display substrate further comprises a base substrate, and the pixel circuit is on a main surface of the base substrate; the pixel circuit further comprises a storage capacitor, a first electrode of the storage capacitor is electrically connected to a gate electrode of the driving transistor, and a second electrode of the storage capacitor is electrically connected to a first power voltage terminal to receive a first power voltage; the gate electrode of the driving transistor comprises a bottom gate, in a direction perpendicular to the main surface of the base substrate, the bottom gate is on a side of the active layer of the driving transistor close to the base substrate; the first electrode of the storage capacitor, the second electrode of the storage capacitor, and the bottom gate of the driving transistor are in different layers from each other, and both the first electrode of the storage capacitor and the second electrode of the storage capacitor are on a side of the active layer of the driving transistor close to the base substrate.

For example, in the display substrate provided by at least one embodiment of the present disclosure, the pixel circuit further comprises a control transistor, a first electrode of the control transistor is electrically connected to the gate electrode of the driving transistor, and a material of an active layer of the control transistor is the metal oxide semiconductor material; the pixel circuit comprises a first reset transistor, the first reset transistor is configured to write a first reset signal to the gate electrode of the driving transistor under a control of a first reset control signal; the pixel circuit further comprises a compensation transistor, the compensation transistor is configured to compensate for a signal applied to the gate electrode of the driving transistor in response to a compensation scanning signal and the data signal; the control transistor comprises at least one of the first reset transistor and the compensation transistor, and a material of an active layer of at least one of the first reset transistor and the compensation transistor is the metal oxide semiconductor material.

For example, in the display substrate provided by at least one embodiment of the present disclosure, the gate electrode of the driving transistor further comprises a top gate, in the direction perpendicular to the main surface of the base substrate, the top gate is on a side of the active layer of the driving transistor away from the base substrate; the first electrode of the storage capacitor is electrically connected to the top gate of the driving transistor, and the second electrode of the storage capacitor is electrically connected to the first power voltage terminal.

For example, in the display substrate provided by at least one embodiment of the present disclosure, an orthographic projection of the storage capacitor on the main surface of the base substrate at least partially overlaps with an orthographic projection of the driving transistor on the main surface of the base substrate.

For example, in the display substrate provided by at least one embodiment of the present disclosure, the first electrode of the storage capacitor is on a side of the second electrode of the storage capacitor close to the base substrate, and an orthographic projection of the first electrode of the storage capacitor on the main surface of the base substrate is within a range of an orthographic projection of the second electrode of the storage capacitor on the main surface of the base substrate, an orthographic projection of the bottom gate of the driving transistor on the main surface of the base substrate is within a range of an orthographic projection of the first electrode of the storage capacitor on the main surface of the base substrate.

For example, in the display substrate provided by at least one embodiment of the present disclosure, the gate electrode of the driving transistor further comprises a top gate, in the direction perpendicular to the main surface of the base substrate, the top gate of the driving transistor is on a side of the active layer of the driving transistor away from the base substrate; an orthographic projection of the top gate of the driving transistor on the main surface of the base substrate is within a range of the orthographic projection of the bottom gate of the driving transistor on the main surface of the base substrate.

For example, in the display substrate provided by at least one embodiment of the present disclosure, the active layer of the control transistor and the active layer of the driving transistor are in a same layer; the control transistor comprises a bottom gate, the bottom gate of the control transistor and the second electrode of the storage capacitor are in a same layer, or, the bottom gate of the control transistor and the bottom gate of the driving transistor are in a same layer.

For example, in the display substrate provided by at least one embodiment of the present disclosure, an orthographic projection of the storage capacitor on the main surface of the base substrate does not overlap with an orthographic projection of the driving transistor on the main surface of the base substrate and does not overlap with an orthographic projection of the control transistor on the main surface of the base substrate.

For example, in the display substrate provided by at least one embodiment of the present disclosure, an orthographic projection of the storage capacitor on the main surface of the base substrate at least partially overlaps with an orthographic projection of the control transistor on the main surface of the base substrate.

For example, in the display substrate provided by at least one embodiment of the present disclosure, the active layer of the control transistor and the active layer of the driving transistor are in a same layer; the control transistor comprises a bottom gate, and the bottom gate of the control transistor and the bottom gate of the driving transistor are in a same layer; an orthographic projection of the first electrode of the storage capacitor on the main surface of the base substrate is within a range of an orthographic projection of the second electrode of the storage capacitor on the main surface of the base substrate, and an orthographic projection of the bottom gate of the control transistor on the main surface of the base substrate is within a range of the orthographic projection of the first electrode of the storage capacitor on the main surface of the base substrate.

For example, in the display substrate provided by at least one embodiment of the present disclosure, the gate electrode of the control transistor further comprises a top gate, in the direction perpendicular to the main surface of the base substrate, the top gate of the control transistor is on a side of the active layer of the control transistor away from the base substrate; an orthographic projection of the top gate of the control transistor on the main surface of the base substrate is within a range of an orthographic projection of the bottom gate of the control transistor on the main surface of the base substrate.

For example, in the display substrate provided by at least one embodiment of the present disclosure, an orthographic projection of the storage capacitor on the main surface of the base substrate at least partially overlaps with an orthographic projection of the driving transistor on the main surface of the base substrate and at least partially overlaps with an orthographic projection of at least one control transistor on the main surface of the base substrate.

For example, in the display substrate provided by at least one embodiment of the present disclosure, the active layer of the control transistor and the active layer of the driving transistor are in a same layer; the control transistor comprises a bottom gate, and the bottom gate of the control transistor and the bottom gate of the driving transistor are in a same layer; an orthographic projection of the first electrode of the storage capacitor on the main surface of the base substrate is within a range of an orthographic projection of the second electrode of the storage capacitor on the main surface of the base substrate, and an orthographic projection of the bottom gate of the driving transistor on the main surface of the base substrate and an orthographic projection of the bottom gate of the control transistor on the main surface of the base substrate are both within a range of the orthographic projection of the first electrode of the storage capacitor on the main surface of the base substrate.

For example, in the display substrate provided by at least one embodiment of the present disclosure, an orthographic projection of an interval between the driving transistor and the control transistor on the main surface of the base substrate is within a range of the orthographic projection of the storage capacitor on the main surface of the base substrate.

For example, in the display substrate provided by at least one embodiment of the present disclosure, an orthographic projection of the storage capacitor on the main surface of the base substrate does not overlap with an orthographic projection of the driving transistor on the main surface of the base substrate, and at least partially overlaps with orthographic projections of a plurality of the control transistors on the main surface of the base substrate.

For example, in the display substrate provided by at least one embodiment of the present disclosure, all of active layers of the plurality of control transistors and the active layer of the driving transistor are in a same layer; each of the plurality of control transistors comprises a bottom gate, and the bottom gates of the plurality of control transistors and the bottom gate of the driving transistor are in a same layer; an orthographic projection of the first electrode of the storage capacitor on the main surface of the substrate is within a range of an orthographic projection of the second electrode of the storage capacitor on the main surface of the substrate, and orthographic projections of the bottom gates of the plurality of control transistors on the main surface of the substrate are all within a range of the orthographic projection of the first electrode of the storage capacitor on the main surface of the substrate.

For example, in the display substrate provided by at least one embodiment of the present disclosure, the second electrode of the storage capacitor is between the first electrode of the storage capacitor and the bottom gate of the driving transistor.

For example, in the display substrate provided by at least one embodiment of the present disclosure, the bottom gate of the driving transistor and the second electrode of the storage capacitor are in a same layer, and is between the bottom gates of a plurality of the control transistors and the first electrode of the storage capacitor.

For example, in the display substrate provided by at least one embodiment of the present disclosure, the bottom gate of the driving transistor and the second electrode of the storage capacitor are in a same layer, and the control transistor does not comprise a gate electrode between a layer where the second electrode of the storage capacitor is located and the active layer of the control transistor.

For example, in the display substrate provided by at least one embodiment of the present disclosure, the first electrode of the driving transistor is on a side of the active layer of the driving transistor away from the base substrate, the first electrode of the driving transistor is electrically connected to the active layer of the driving transistor through a first via, and electrically connected to the bottom gate of the driving transistor through a second via.

For example, in the display substrate provided by at least one embodiment of the present disclosure, the pixel circuit further comprises a switch transistor, and a material of an active layer of the switch transistor of the pixel circuit is the silicon semiconductor material; in the direction perpendicular to the main surface of the base substrate, the active layer of the switch transistor of the pixel circuit is on a side of the storage capacitor close to the base substrate; or, materials of active layers materials of all transistors of the pixel circuit are metal oxide semiconductor materials.

For example, in the display substrate provided by at least one embodiment of the present disclosure, the base substrate comprises a display region and a non-display region at least partially surrounding the display region, the display substrate further comprises a scanning drive circuit in the non-display region, the scanning drive circuit comprises a switch transistor, and the scanning drive circuit is configured to provide a driving scanning signal to the pixel circuit of the display region; in the direction perpendicular to the main surface of the base substrate, an active layer of the switch transistor of the scanning drive circuit is on a side of the storage capacitor close to the base substrate; a material of the active layer of the switch transistor of the scanning drive circuit is the silicon semiconductor material; a first electrode of the switch transistor of the scanning drive circuit and a second electrode of the switch transistor of the scanning drive circuit are electrically connected with the active layer of the switch transistor of the scanning drive circuit through a third via and a fourth via respectively.

For example, in the display substrate provided by at least one embodiment of the present disclosure, the base substrate comprises a display region and a non-display region at least partially surrounding the display region, the display substrate further comprises a bending portion in the non-display region, the bending portion comprises a driving circuit board and a connection wire, wherein the connection wire is electrically connected to the driving circuit board and electrically connected to a signal wire extending to the display region, the signal wire is electrically connected to the pixel circuit to provide a display signal to the pixel circuit; the display substrate is a flexible display substrate which comprises a flexible organic layer and an inorganic insulation layer, the inorganic insulation layer and the flexible organic layer are stacked on the main surface of the base substrate, and the inorganic insulation layer is on a side of the flexible organic layer away from the base substrate, the inorganic insulation layer comprises a first sub inorganic layer between the first electrode of the storage capacitor and the second electrode of the storage capacitor, and a second sub inorganic layer between the second electrode of the storage capacitor and the bottom gate of the driving transistor; the display substrate comprises at least a fifth via that runs through the inorganic insulation layer, and the connection wire is at least partially in the fifth via.

At least one embodiment of the present disclosure further provides a display apparatus, the display apparatus includes any of the display substrates provided by the embodiments of the present disclosure.

At least one embodiment of the present disclosure further provides a manufacture method of a display substrate, the manufacture method includes: forming a sub-pixel, including forming a pixel circuit of the sub-pixel includes, in which the pixel circuit includes a light-emitting device and a driving transistor, the driving transistor is configured to control a magnitude of a driving current flowing through the light-emitting device according to a data signal; and forming a data transistor of the pixel circuit, in which the data transistor is configured to write the data signal into a first electrode of the driving transistor in response to a data driving signal; a material of an active layer of the driving transistor includes a metal oxide semiconductor material, and a material of an active layer of the data transistor includes a silicon semiconductor material.

At least one embodiment of the present disclosure provides a manufacture method of a display substrate, the manufacture method includes: providing a base substrate and forming a sub-pixel on a main surface of the base substrate, including forming a pixel circuit of the sub-pixel, in which the pixel circuit includes a light-emitting device and a driving transistor, the driving transistor is configured to control a magnitude of a driving current flowing through the light-emitting device according to a data signal; the pixel circuit further includes a storage capacitor, a first electrode of the storage capacitor is electrically connected to a gate electrode of the driving transistor, and a second electrode of the storage capacitor is electrically connected to a first power voltage terminal to receive a first power voltage; the gate electrode of the driving transistor includes a bottom gate, in a direction perpendicular to the main surface of the base substrate, the bottom gate is on a side of the active layer of the driving transistor close to the base substrate; the first electrode of the storage capacitor, the second electrode of the storage capacitor, and the bottom gate of the driving transistor are in different layers from each other, and both the first electrode of the storage capacitor and the second electrode of the storage capacitor are on a side of the active layer of the driving transistor away from the base substrate.

At least one embodiment of the present disclosure provides a manufacture method of a display substrate, the manufacture method includes: providing a base substrate and forming a sub-pixel on a main surface of the base substrate, including forming a pixel circuit of the sub-pixel, in which the pixel circuit includes a light-emitting device and a driving transistor, the driving transistor is configured to control a magnitude of a driving current flowing through the light-emitting device according to a data signal; the pixel circuit further includes a storage capacitor, a first electrode of the storage capacitor is electrically connected to a gate electrode of the driving transistor, and a second electrode of the storage capacitor is electrically connected to a first power voltage terminal to receive a first power voltage; an orthographic projection of the storage capacitor on the main surface of the base substrate at least partially overlaps with an orthographic projection of the driving transistor on the main surface of the base substrate.

### BRIEF DESCRIPTION OF DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1A is a planar schematic diagram of a display substrate provided by at least one embodiment of the present disclosure;

FIG. 1B is a planar schematic diagram of some pixels in a display region of FIG. 1A;

FIG. 2 is a schematic diagram of a pixel circuit provided by at least one embodiment of the present disclosure;

FIG. 3 is a partial cross-sectional schematic diagram of a pixel circuit of a display substrate provided by at least one embodiment of the present disclosure;

FIG. 4 is a partial cross-sectional schematic diagram of a pixel circuit of another display substrate provided by at least one embodiment of the present disclosure;

FIG. 5 is a partial cross-sectional schematic diagram of a pixel circuit of another display substrate provided by at least one embodiment of the present disclosure;

FIG. 6 is a partial cross-sectional schematic diagram of a pixel circuit of another display substrate provided by at least one embodiment of the present disclosure;

FIG. 7 is a partial cross-sectional schematic diagram of a pixel circuit of another display substrate provided by at least one embodiment of the present disclosure;

FIG. 8 is a partial cross-sectional schematic diagram of a pixel circuit of another display substrate provided by at least one embodiment of the present disclosure;

FIG. 9 is a partial cross-sectional schematic diagram of a pixel circuit of another display substrate provided by at least one embodiment of the present disclosure;

FIG. 10 is a partial cross-sectional schematic diagram of a pixel circuit of another display substrate provided by at least one embodiment of the present disclosure;

FIG. 11 is a partial cross-sectional schematic diagram of a pixel circuit of another display substrate provided by at least one embodiment of the present disclosure;

FIG. 12 is a schematic diagram of a display apparatus provided by an embodiment of the present disclosure; and

FIG. 13A to FIG. 13C are schematic diagrams of a manufacture method of a display substrate provided by an embodiment of the present disclosure.

### DETAILED DESCRIPTION

In order to make objects, technical details and advantages of the embodiments of the disclosure apparent, the technical solutions of the embodiments will be described in a clear and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “comprise,” “comprising,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly. “On,” “under,” “left,” “right” and the like are only used to indicate relative position relationship, and when the position of the object which is described is changed, the relative position relationship may be changed accordingly.

The interpretation of the terms used in the present disclosure is as follows.
(1) The meaning of integrated structure: the case that structure A and structure B form an integrated structure refers to the case that there are no seams between the structure A and the structure B, and the structure A and the structure B are a uniformly textured integrated structure, such as formed through single one patterning process. The letters A and B are used to refer to the corresponding structures described in the text.
(2) The meaning of in the(a) same layer: illustrating the relationship between a plurality of structures formed by a layer formed by the same material being subjected to single one patterning process. The “in the(a) same layer” here does not always refer to the plurality of structures with the same thickness or the plurality of structures with the same height in the cross-sectional view.
(3) The meaning of single one patterning process: using a mask to pattern a certain layer through a single one exposure process.

The drawings in the present disclosure are not strictly drawn to actual proportions, and the number of sub-pixels on the display substrate is not limited to the number shown in the figure. The specific dimensions and quantities of each structure can be determined according to actual needs. The drawings described in the present disclosure are only structural diagrams.

In the existing LTPO display substrate, the driving transistor of the pixel circuit in the display region is LTPS TFT, and some of switch transistors in the pixel circuit are LTPS TFT and some are Oxide TFT. Compared to Oxide TFT, LTPS TFT has larger hysteresis and larger off state current Ioff, which can affect the display quality of OLED display substrates, while Oxide TFT has smaller hysteresis and smaller off state current Ioff. However, the migration rate of Oxide TFT is lower than the migration rate of LTPS TFT, resulting in a lower on state current Ion of Oxide TFT. When using Oxide TFT as a switch transistor of the pixel circuit in the display region, the low Ion will affect the driving ability of the Oxide TFT, leading to a decrease in the accuracy of the signal transmitted through the switch transistor.

At least one embodiment of the present disclosure provides a display substrate, the display substrate includes a sub-pixel, the sub-pixel includes a pixel circuit, the pixel circuit includes a light-emitting device and a driving transistor, the driving transistor is configured to control a magnitude of a driving current flowing through the light-emitting device according to a data signal; the pixel circuit further includes a data transistor, the data transistor is configured to write the data signal into a first electrode of the driving transistor in response to a data driving signal; a material of an active layer of the driving transistor includes a metal oxide semiconductor material, and a material of an active layer of the data transistor includes a silicon semiconductor material.

At least one embodiment of the present disclosure provides a display substrate, the display substrate includes a sub-pixel, the sub-pixel includes a pixel circuit, the pixel circuit includes a light-emitting device and a driving transistor, the driving transistor is configured to control a magnitude of a driving current flowing through the light-emitting device according to a data signal; the display substrate further includes a base substrate, and the pixel circuit is on a main surface of the base substrate; the pixel circuit further includes a storage capacitor, a first electrode of the storage capacitor is electrically connected to a gate electrode of the driving transistor, and a second electrode of the storage capacitor is electrically connected to a first power voltage terminal to receive a first power voltage; the gate electrode of the driving transistor includes a bottom gate, in a direction perpendicular to the main surface of the base substrate, the bottom gate is on a side of the active layer of the driving transistor close to the base substrate; the first electrode of the storage capacitor, the second electrode of the storage capacitor, and the bottom gate of the driving transistor are in different layers from each other, and both the first electrode of the storage capacitor and the second electrode of the storage capacitor are on a side of the active layer of the driving transistor away from the base substrate.

At least one embodiment of the present disclosure provides a display substrate, the display substrate includes a sub-pixel, the sub-pixel includes a pixel circuit, the pixel circuit includes a light-emitting device and a driving transistor, the driving transistor is configured to control a magnitude of a driving current flowing through the light-emitting device according to a data signal; the display substrate further includes a base substrate, and the pixel circuit is on a main surface of the base substrate; the pixel circuit further includes a storage capacitor, a first electrode of the storage capacitor is electrically connected to a gate electrode of the driving transistor, and a second electrode of the storage capacitor is electrically connected to a first power voltage terminal to receive a first power voltage; an orthographic projection of the storage capacitor on the main surface of the base substrate at least partially overlaps with an orthographic projection of the driving transistor on the main surface of the base substrate.

At least one embodiment of the present disclosure further provides a display apparatus, the display apparatus includes any of the display substrates provided by the embodiments of the present disclosure.

At least one embodiment of the present disclosure further provides a manufacture method of a display substrate, the manufacture method includes: forming a sub-pixel, including forming a pixel circuit of the sub-pixel includes, in which the pixel circuit includes a light-emitting device and a driving transistor, the driving transistor is configured to control a magnitude of a driving current flowing through the light-emitting device according to a data signal; and forming a data transistor of the pixel circuit, in which the data transistor is configured to write the data signal into a first electrode of the driving transistor in response to a data driving signal; a material of an active layer of the driving transistor includes a metal oxide semiconductor material, and a material of an active layer of the data transistor includes a silicon semiconductor material.

At least one embodiment of the present disclosure provides a manufacture method of a display substrate, the manufacture method includes: providing a base substrate and forming a sub-pixel on a main surface of the base substrate, including forming a pixel circuit of the sub-pixel, in which the pixel circuit includes a light-emitting device and a driving transistor, the driving transistor is configured to control a magnitude of a driving current flowing through the light-emitting device according to a data signal; the pixel circuit further includes a storage capacitor, a first electrode of the storage capacitor is electrically connected to a gate electrode of the driving transistor, and a second electrode of the storage capacitor is electrically connected to a first power voltage terminal to receive a first power voltage; the gate electrode of the driving transistor includes a bottom gate, in a direction perpendicular to the main surface of the base substrate, the bottom gate is on a side of the active layer of the driving transistor close to the base substrate; the first electrode of the storage capacitor, the second electrode of the storage capacitor, and the bottom gate of the driving transistor are in different layers from each other, and both the first electrode of the storage capacitor and the second electrode of the storage capacitor are on a side of the active layer of the driving transistor away from the base substrate.

At least one embodiment of the present disclosure provides a manufacture method of a display substrate, the manufacture method includes: providing a base substrate and forming a sub-pixel on a main surface of the base substrate, including forming a pixel circuit of the sub-pixel, in which the pixel circuit includes a light-emitting device and a driving transistor, the driving transistor is configured to control a magnitude of a driving current flowing through the light-emitting device according to a data signal; the pixel circuit further includes a storage capacitor, a first electrode of the storage capacitor is electrically connected to a gate electrode of the driving transistor, and a second electrode of the storage capacitor is electrically connected to a first power voltage terminal to receive a first power voltage; an orthographic projection of the storage capacitor on the main surface of the base substrate at least partially overlaps with an orthographic projection of the driving transistor on the main surface of the base substrate.

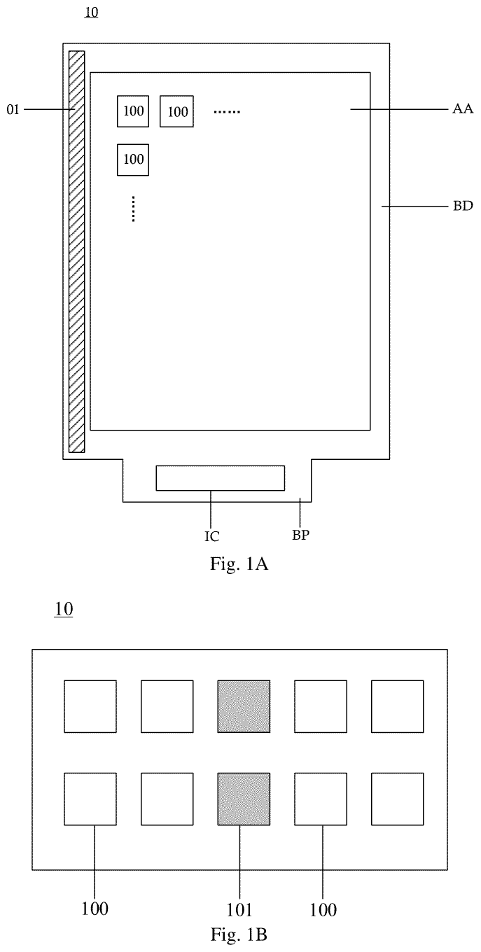

Illustratively, FIG. 1A is a planar schematic diagram of a display substrate provided by at least one embodiment of the present disclosure. As shown in FIG. 1A, the base substrate 1 includes a display region AA and a non-display region BA at least partially surrounding the display region.

FIG. 1B is a planar schematic diagram of some pixels in the display region shown in FIG. 1A. As shown in FIG. 1B, for example, the display substrate 10 includes a plurality of pixels 100 arranged in an array, at least some pixels 100 of the plurality of pixels 100 include a plurality of sub-pixels, and at least some sub-pixels of the plurality of sub-pixels include a light-emitting device and a pixel circuit for driving the light-emitting device to emit light. For example, the pixel circuit may include a 2T1C (i.e. two transistors and a capacitor) pixel circuit, a 4T2C, 5T1C, 7T1C, or nTmC (where n and m are positive integers) pixel circuit. For example, in different embodiments, the pixel circuit may further include a compensation sub-circuit, which includes an internal compensation sub-circuit or an external compensation sub-circuit, and the compensation sub-circuit may include a transistor, a capacitor, etc. For example, as needed, the pixel circuit may further include a reset circuit, a light-emitting control sub-circuit, a detection circuit, etc.

For example, as shown in FIG. 1B, the plurality of pixels 100 are in the display region. For example, in the display substrate 10 provided by some embodiments, some pixels of the plurality of pixels 100 are dummy pixels 101, which do not participate in display work. Each dummy pixel 101 includes a plurality of dummy sub-pixels, but does not include sub-pixels that play a display driving role. Of course, the display region may also exclude dummy pixels.

For example, the display substrate 10 is an organic light-emitting diode (OLED) display substrate, and the light-emitting device is an OLED. The display substrate 10 may also include a plurality of scanning lines and a plurality of data lines for providing scanning signals (such as gate lines, control signals, refer to FIG. 5) and data signals to drive the plurality of sub-pixels. As needed, the display substrate 10 may further include power lines, detection lines, etc.

It should be noted that the term “the electrode where the active layer of the control transistor is located being directly electrically connected to the gate electrode of the driving transistor and the first electrode of the control transistor” refers to that the electrode where the active layer of the control transistor is located directly contacts the gate electrode of the driving transistor and the first electrode of the control transistor, thereby electrically connect the gate electrode of the driving transistor with the first electrode of the control transistor, instead of indirectly connecting the first electrode of the active layer of the control transistor with the gate electrode of the driving transistor through other conductive structures (such as conductive structures located in other layers).

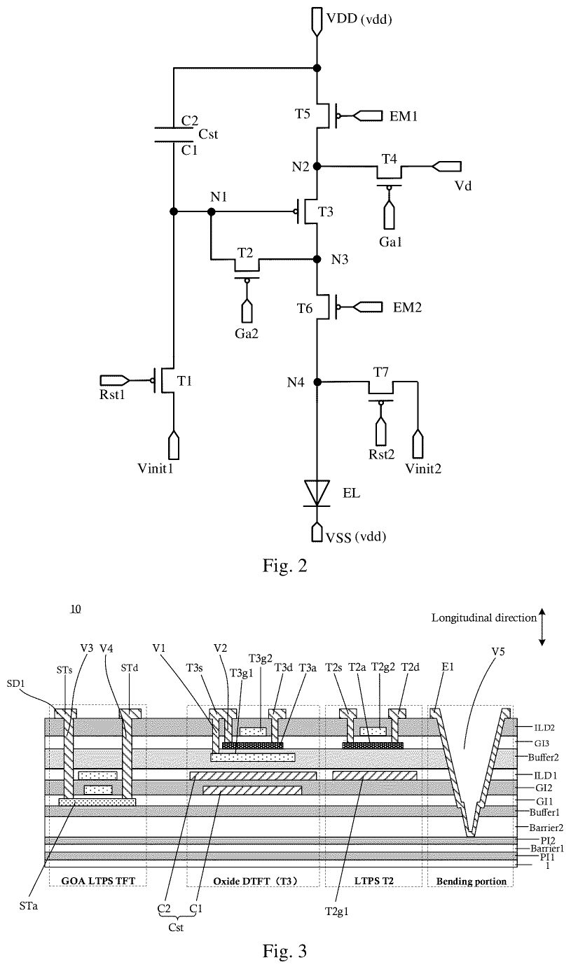

For example, FIG. 2 is a schematic diagram of a pixel circuit provided by at least one embodiment of the present disclosure. Here, taking the 7T1C pixel circuit shown in FIG. 2 as an example to illustrate the structure of sub-pixel of the display substrate.

As shown in FIG. 2, the pixel circuit includes first to seventh transistors T1, T2, T3, T4, T5, T6, T7, and includes a storage capacitor Cst. For example, the third transistor T3 is used as the driving transistor, and the first transistor, the second transistor, the forth transistor, the fifth transistor, the sixth transistor and the seventh transistor are used as switch transistors.

For example, as shown in FIG. 2, the pixel circuit of the display substrate 10 provided by the embodiments of the present disclosure includes a light-emitting device EL, a driving transistor T3, and a data transistor T4. The gate electrode of the driving transistor T3 is electrically connected to the first node N1; the first electrode of the driving transistor T3 is electrically connected to the second node N2; the second electrode of the driving transistor T3 is electrically connected to the third node N3. The gate electrode of data transistor T4 is electrically connected to the first scanning line (first scanning signal terminal Ga1) to receive the first scanning signal, the first electrode of the data transistor T4 is connected to the data line (data signal terminal Vd) to receive the data signal, and the second electrode of data transistor T4 is electrically connected to the second node N2. The driving transistor T3 is configured to control the magnitude of the driving current flowing through the light-emitting device EL based on the data signal.

For example, as shown in FIG. 2, the gate electrode of the compensation transistor T2 is electrically connected to the second scanning line (second scanning signal terminal Ga2) to receive the second scanning signal. The compensation transistor T2 is configured to compensate for the signal applied to the gate electrode of the driving transistor T3 in response to the compensation scanning signal and data signal. The first electrode T3s of the compensation transistor T2 is electrically connected to the second electrode of the driving transistor T3 (third node N3), and the second electrode of the compensation transistor T2 is electrically connected to the gate electrode of the driving transistor T3 (first node N1).

For example, as shown in FIG. 2, the pixel circuit further includes a storage capacitor Cst, the storage capacitor Cst includes a first electrode C1 and a second electrode C2. The first electrode C1 of the storage capacitor Cst is electrically connected to the gate electrode of the driving transistor T3, and the first electrode C1 is electrically connected to the gate electrode of the driving transistor T3 (first node N1); the second electrode C2 of the storage capacitor Cst is electrically connected to the first power voltage terminal VDD to receive the first power voltage VDD.

For example, as shown in FIG. 2, the gate electrode of the first light-emitting control transistor T5 is electrically connected to the first light-emitting control line (first light-emitting control terminal EM1) to receive the first light-emitting control signal, the first electrode of the first light-emitting control transistor T5 is electrically connected to the first voltage terminal vdd to receive the first power voltage VDD, and the second electrode of the first light-emitting control transistor T5 is electrically connected to the second node N2.

For example, the light-emitting device EL is specifically implemented as a light-emitting diode (LED), which may be an organic light-emitting diode (OLED), a quantum dot light-emitting diode (QLED), or an inorganic light-emitting diode, and may be a micro light-emitting diode (Micro LED) or a micro OLED. For example, the light-emitting device EL may be a top emitting structure, a bottom emitting structure, or a double-sided emitting structure. The light-emitting device EL may emit red light, green light, blue light, or white light, etc. The embodiments of the present disclosure do not limit the specific structure of the light-emitting device.

For example, the first electrode of the light-emitting device EL (e.g. anode) is connected to the fourth node N4, and is configured to be connected to the second electrode of the driving transistor T3 (third node N3) through the second light-emitting control transistor T6, and the second electrode of the light-emitting device EL (e.g. cathode) is electrically connected to the common power voltage terminal VSS to receive the common power voltage VSS, the current flowing from the second electrode of the driving transistor T3 into the light-emitting device EL determines the brightness of the light-emitting device. For example, the common power voltage terminal VSS may be grounded, that is, the common power voltage VSS may be 0V. For example, the common power voltage VSS may also be a negative voltage.

For example, the gate electrode of the second light-emitting control transistor T6 is electrically connected to the second light-emitting control line (second light-emitting control terminal EM2) to receive the second light-emitting control signal, the first electrode of the second light-emitting control transistor T6 is electrically connected to the second electrode of the driving transistor T3 (third node N3), and the second electrode of the second light-emitting control transistor T6 is electrically connected to the first electrode of the light-emitting device EL (fourth node N4).

Referring to FIG. 2, for example, the pixel circuit further includes a first reset transistor T1, the first reset transistor T1 is configured to write the first reset signal Vinit1 to the gate electrode of the driving transistor T3 under the control of the first reset control signal Rst1. For example, the gate electrode of the first reset transistor T1 is connected to the first reset control terminal Rst1 to receive the first reset control signal Rst1, the first electrode of the first reset transistor T1 is connected to the first reset voltage terminal Vinit1 to receive the first reset voltage Vinit1, and the second electrode of the first reset transistor T1 is configured to be connected to the first node N1. For example, the pixel circuit further includes a second reset transistor T7, the gate electrode of second reset transistor T7 is connected to the second reset control terminal Rst2 to receive the second reset control signal Rst2, the first electrode of the second reset transistor T7 is connected to the second reset voltage terminal Vinit2 to receive the second reset voltage Vinit2, and the second electrode of the second reset transistor T7 is configured to be connected to the fourth node N4.

For example, the first reset signal Vinit1 and the second reset signal Vinit2 are the same signal, coming from the same reset signal wire connected to the same reset signal terminal, thereby saving one reset signal wire. Of course, the first reset signal Vinit1 and the second reset signal Vinit2 may also be two independent signals.

It should be noted that the transistors used in the embodiments of the present disclosure may all be thin film transistors, field-effect transistors, or other switching devices with similar characteristics. The embodiments of the present disclosure are illustrated using thin film transistors as examples. The source electrode and drain electrode of the transistor used here may be symmetrical in structure, so the source electrode and drain electrode can be structurally indistinguishable. In the embodiments of the present disclosure, in order to distinguish the two electrodes of the transistor except for the gate electrode, one electrode is directly described as the first electrode and the other electrode is described as the second electrode.

In addition, according to the characteristics of the transistors, the transistors can be divided into N-type transistors and P-type transistors. In the case that the transistor is a P-type transistor, the turn-on voltage is a low-level voltage (such as 0V, −5V, −10V or other suitable voltage), and the turn-off voltage is a high-level voltage (such as 5V, 10V or other suitable voltage); in the case that the transistor is an N-type transistor, the turn-on voltage is a high-level voltage (e.g. 5V, 10V or other suitable voltage), and the turn-off voltage is a low-level voltage (e.g. 0V, −5V, −10V or other suitable voltage). For example, as shown in FIG. 2, taking the case that all the first to seventh transistors T1-T7 are P-type transistors as an example to illustrate. However, the embodiments of the present disclosure do not limit the type of each transistor. As the type of a transistor changes, the connection relationship in the circuit can be adjusted accordingly.

FIG. 3 is a partial cross-sectional schematic diagram of a pixel circuit of a display substrate provided by at least one embodiment of the present disclosure. Referring to FIG. 3, the display substrate 10 further includes a base substrate 1, and the pixel circuit is on the main surface of the base substrate 1. FIG. 3 shows the driving transistor T3 (DTFT) of the pixel circuit. For example, in at least one embodiment of the present disclosure, the material of the active layer T3a of the driving transistor T3 is a metal oxide semiconductor material, and the material of the active layer of the data transistor T4 is a silicon semiconductor material, that is, the driving transistor T3 is an oxide transistor (Oxide TFT), while the data transistor T4 is a low-temperature polycrystalline silicon transistor (LTPS TFT), so as to take advantage of the small hysteresis and turn-off state current Ioff of Oxide TFT to allow the driving transistor T3 to have good driving performance. At the same time, due to the lower mobility of Oxide TFT than that of LTPS TFT, the turn-on state current Ion of Oxide TFT is also lower, in the case where Oxide TFT is used as a switch transistor of the pixel circuits in the display region, the low Ion can affect its driving ability, leading to a decrease in the accuracy of the signal transmitted through the switch transistor. As one of the switch transistors of the pixel circuit, the data transistor T4 adopts LTPS TFT, which can avoid the problem of reducing the accuracy of the transmitted data signal caused by the data transistor T4 being the Oxide TFT. Due to the fact that the data signal is used to control the grayscale of the display, compared to other switch transistors of the pixel circuits except for the driving transistor T3, the ability of the data transistor T4 to transmit signals has a more significant impact on the display image, so in the case where the driving transistor T3 is Oxide TFT and the data transistor T4 is LTPS TFT, the advantages of these two types of transistors can be fully utilized to achieve better display quality.

For example, the above metal oxide semiconductor material includes indium gallium zinc oxide (IGZO); alternatively, the above metal oxide semiconductor material includes indium gallium tin oxide (IGTO) which replaces zinc in IGZO with tin (Sn); alternatively, the above metal oxide semiconductor material includes indium gallium zinc tin oxide (IGZTO), in which tin is added to IGZO. Of course, the above metal oxide semiconductor material is not limited to the types listed above, and the embodiments of the present disclosure do not limit the specific type of the metal oxide semiconductor material.

In a display substrate provided by the present disclosure, referring to FIG. 3, the display substrate includes the above sub-pixel 100, the sub-pixel 100 includes a pixel circuit, the pixel circuit includes a light-emitting device EL and a driving transistor T3, and the driving crystal T3 is configured to control the magnitude of the driving current flowing through the light-emitting device EL based on the data signal; the display substrate 10 further includes a base substrate 1, and the pixel circuit is provided on the main surface of the base substrate 1. The pixel circuit further includes a storage capacitor Cst, and the first electrode C1 of the storage capacitor Cst is electrically connected to the gate electrode of the driving transistor T3, the second electrode C2 of the storage capacitor Cst is electrically connected to the first power voltage terminal vdd to receive the first power voltage VDD. For example, the gate electrode of the driving transistor T3 includes a bottom gate T3g1 and a top gate T3g2. In the direction perpendicular to the main surface of the base substrate 1, the bottom gate T3g1 of the driving transistor T3 is located on the side of the active layer T3a of the driving transistor T3 close to the base substrate 1, and the top gate T3g2 of the driving transistor T3 is located on the side of the active layer T3a of the driving transistor T3 away from the base substrate 1; the first electrode C1 of the storage capacitor Cst, the second electrode C2 of the storage capacitor Cst, and the bottom gate T3g1 of the driving transistor T3 are in different layers from each other. In this way, there is more space in the film layer where the first electrode C1 of the storage capacitor Cst and the second electrode C2 of the storage capacitor Cst are located to expand the area of the first electrode C1 and the area of the second electrode C2, and to expand the degree of freedom of the positions of the first electrode C1 and the second electrode C2.

For example, referring to FIG. 3, the first electrode C1 of the storage capacitor Cst and the second electrode C2 of the storage capacitor Cst are both located on the side of the active layer T3a of the driving transistor T3 close to the base substrate 1. For example, in the case that the driving transistor T3 includes a bottom gate T3g1, the first electrode C1 of the storage capacitor Cst and the second electrode C2 of the storage capacitor Cst are both located on the side of the bottom gate T3g1 of the driving transistor T3 close to the base substrate 1. In some embodiments, the driving transistor T3 does not include a bottom gate T3g1 but only a top gate T3g2, that is, the first electrode C1 of the storage capacitor Cst and the second electrode C2 of the storage capacitor Cst are located on the side of the driving transistor T3 close to the base substrate 1. Generally, the source electrode and drain electrode of each transistor and connection wires are provided on the side of the driving transistor T3 away from the base substrate 1, such as in the first conductive layer SD1 described below. Therefore, in the embodiments of the present disclosure, the first electrode C1 of the storage capacitor Cst and the second electrode C2 of the storage capacitor Cst are both located on the side of the bottom gate T3g1 of the driving transistor T3 close to the base substrate 1, the first electrode C1 of the storage capacitor Cst and the second electrode C2 of the storage capacitor Cst can be provided in the space between the insulation layers on the side of the driving transistor T3 close to the base substrate 1, and it is convenient to electrically connect the first electrode C1 of the storage capacitor Cst with the top gate T3g2 of the driving transistor T3. In this way, limited space is utilized to achieve the structure of the pixel circuit and the areas of the first electrode C1 and second electrode C2 of the storage capacitor Cst are increased to increase the capacitance value of the storage capacitor Cst, which can meet the higher requirements for the capacitance value of the storage capacitor Cst in pixel circuit design.

For example, the pixel circuit includes a control transistor, the first electrode of the control transistor is electrically connected to the gate electrode of the driving transistor T3, and the material of the active layer of the control transistor is a metal oxide semiconductor material. The control transistor includes at least one of the first reset transistor T1 and the compensation transistor T2; a material of at least one of active layers of the first reset transistor and the compensation transistor is a metal oxide semiconductor material to reduce the leakage current of the first reset transistor T1 and/or compensation transistor T2, thereby reducing the fluctuation of the signal provided by the gate electrode of the driving transistor T3 and enhancing the reliability of the signal provided to the gate electrode of the driving transistor T3. At the same time, the LTPO display substrate 10, which integrates the oxide transistor (Oxide TFT) and the low-temperature polycrystalline silicon transistor (LTPS TFT), has the advantage of low-frequency driving and can reduce the power consumption of display products.

In FIG. 3, the compensation transistor T2 is used as an example of the control transistor, the control transistor may also be the first reset transistor T1. Of course, the control transistor is not limited to including the compensation transistor T2 and the first reset transistor T1. In other embodiments, all transistors of the pixel circuit, except for the driving transistor, can be control transistors, that is, the material of the active layer of the control transistor can be silicon semiconductor material, and the pixel circuit is not limited to the 7T1C pixel circuit shown in FIG. 2.

For example, referring to FIG. 3, the first electrode C1 of the storage capacitor Cst is electrically connected to the top gate T3g2 of the driving transistor T3, and the second electrode C2 of the storage capacitor Cst is electrically connected to the first power voltage terminal vdd. Of course, in other embodiments, the first electrode C1 of the storage capacitor Cst may also be electrically connected to the top gate T3g2 of the driving transistor T3.

For example, at least one embodiment of the present disclosure further provides a display substrate, the display substrate includes the above sub-pixel 100, the sub-pixel 100 includes a pixel circuit, the pixel circuit includes a light-emitting device EL and a driving transistor T3, and the driving transistor T3 is configured to control the magnitude of the driving current flowing through the light-emitting device EL based on the data signal; the display substrate 10 further includes a base substrate 1, and the pixel circuit is provided on the main surface of the base substrate 1. The pixel circuit further includes a storage capacitor Cst, and the first electrode C1 of the storage capacitor Cst is electrically connected to the gate electrode of the driving transistor T3, the second electrode C2 of the storage capacitor Cst is electrically connected to the first power voltage terminal vdd to receive the first power voltage VDD; the orthographic projection of the storage capacitor Cst on the main surface of the base substrate 1 at least partially overlaps with the orthographic projection of the driving transistor T3 on the main surface of the base substrate 1. Referring to FIG. 3, the orthographic projection of the storage capacitor Cst on the main surface of the base substrate 1 at least partially overlaps with the orthographic projection of the driving transistor T3 on the main surface of the base substrate 1. Therefore, not only can the space below the driving transistor T3 be used to set the first electrode C1 and second electrode C2 of the storage capacitor Cst, but also the storage capacitor Cst is close to the driving transistor T3, thereby facilitating the electrical connection between the first electrode C1 of the storage capacitor Cst and the gate electrode of the driving transistor T3, avoiding design difficulties caused by winding the connection wire between the first electrode C1 of the storage capacitor Cst and the gate electrode of the driving transistor T3 for electrical connection.

For example, referring to FIG. 3, the first electrode C1 of the storage capacitor Cst is provided on the side of the second electrode C2 of the storage capacitor Cst close to the base substrate 1, that is, the second electrode C2 of the storage capacitor Cst is provided between the first electrode C1 of the storage capacitor Cst and the bottom gate T3g1 of the driving transistor T3. The orthographic projection of the first electrode C1 of the storage capacitor Cst on the main surface of the base substrate 1 is within the range of the orthographic projection of the second electrode C2 of the storage capacitor Cst on the main surface of the base substrate 1. The second electrode C2 covers the first electrode C1 to ensure the uniformity of the size of the storage capacitor Cst. Generally, the first electrode C1 is prepared first, and then the second electrode C2 is prepared above the first electrode C1 (on the side away from the base substrate 1). If the orthographic projection of the second electrode C2 on the main surface of the base substrate 1 is within the range of the orthographic projection of the first electrode C1 of the storage capacitor Cst on the main surface of the base substrate 1, that is, the first electrode C1 located below covers the second electrode C2 above the first electrode C1, it is also necessary to consider the influence of uniformity of the critical dimension (CD, the abbreviation is used in the following text) during the etching process for forming the second electrode C2. Therefore, the etching uniformity of the storage capacitor Cst in the case where the first electrode C1 covers the second electrode C2 above the first electrode C1 is not better than the etching uniformity of the storage capacitor Cst in the case where the second electrode C2 above covers the first electrode C1 below the second electrode C2.

For example, the orthographic projection of the bottom gate T3g1 of the driving transistor T3 on the main surface of the base substrate 1 is within the range of the orthographic projection of the first electrode C1 of the storage capacitor Cst on the main surface of the base substrate 1, that is, the first electrode C1 located below the bottom gate T3g1 of the driving transistor T3 covers the bottom gate T3g1 of the driving transistor T3 to ensure etching uniformity of the bottom gate T3g1 of the driving transistor T3. This is because it is necessary to consider the stability and uniformity of the equipment and process. If the first electrode C1 cannot fully cover the bottom gate T3g1 of the driving transistor T3, the bottom gate T3g1 of the driving transistor T3 may have some misalignment with the first electrode C1 (the bottom gate T3g1 partially overlaps with the first electrode C1 in the direction perpendicular to the main surface of the base substrate 1), or the bottom gate T3g1 of the driving transistor T3 is aligned with one edge of the first electrode C1. In these cases, the CD uniformity of the bottom gate T3g1 of the driving transistor T3 is not better than that of the bottom gate T3g1 of the driving transistor T3 when the first electrode C1 completely covers the bottom gate T3g1 of the driving transistor T3. Moreover, if the bottom gate T3g1 of the driving transistor T3 wraps around the first electrode C1, because the bottom gate T3g1 is located below the active layer of the driving transistor T3 (the side close to the side of the base substrate 1), if the size of the bottom gate T3g1 of the driving transistor T3 increases, the size of the driving transistor T3 will also increase, which is not conducive to improving the resolution (PPI) of the display substrate 10.

For example, further, the orthographic projection of the top gate T3g2 of the driving transistor T3 on the main surface of the base substrate 1 is within the range of the orthographic projection of the bottom gate T3g1 of the driving transistor T3 on the main surface of the base substrate 1, that is, the bottom gate T3g1 of the driving transistor T3 covers the top gate T3g2 of the driving transistor T3. Similarly, this is beneficial for improving the CD uniformity of the top gate T3g2 of the driving transistor T3. Moreover, by the top gate T3g2 of the driving transistor T3 covering the bottom gate T3g1 of the driving transistor T3, it is possible to avoid the case that one end of the bottom gate T3g1 of the driving transistor T3 is completely aligned with one end of the top gate T3g2 of the driving transistor T3 because of the influence of factors such as exposure machine alignment deviation and the photoresist coating uniformity of the lithography process. One end that the bottom gate T3g1 of the driving transistor T3 is not aligned with the top gate T3g2 of the driving transistor T3, one end that the bottom gate T3g1 of the driving transistor T3 is aligned with the top gate T3g2 of the driving transistor T3, the thickness of the photoresist and the Taper angle, directly affect the etching rate of the top gate T3g2 of the driving transistor T3 and the Taper angle of the top gate T3g2 of the driving transistor T3 after etching, thereby affecting the CD uniformity of the bottom gate T3g1 of the driving transistor T3. In addition, when the Taper angle of the top gate T3g2 of the driving transistor T3 at one end that the bottom gate T3g1 of the driving transistor T3 is aligned with the top gate T3g2 of the driving transistor T3 increases, the effect of the second interlayer insulation layer ILD2 formed above the top gate T3g2 of the driving transistor T3 planarizing and fully covering the conductive layer below becomes worse, which can easily lead to cracks and cause a short circuit between the top gate T3g2 of the driving transistor T3 and the line in the first conductive layer SD1.

FIG. 3 shows the compensation transistor T2 being the control transistor as an example. For example, referring to FIG. 3, the active layer T2a of the compensation transistor T2 and the active layer T3a of the driving transistor T3 are provided in the same layer, that is, the active layer of the control transistor and the active layer T3a of the driving transistor T3 are provided in the same layer. The materials of the active layer T2 and the active layer T3a are the same, the active layer T2 and the active layer T3a can be formed simultaneously through single one patterning process. The compensation transistor T2 includes a bottom gate T2g1. For example, referring to FIG. 3, the bottom gate T2g1 of the compensation transistor T2 and the second electrode C2 of the storage capacitor Cst are provided in the same layer, and can be formed simultaneously through single one patterning process.

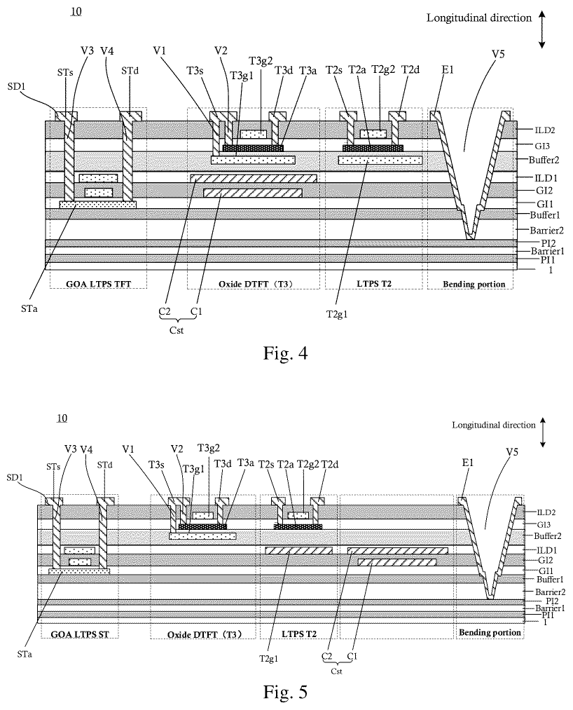

Alternatively, as shown in FIG. 4, the difference between the embodiment shown in FIG. 4 and the embodiment shown in FIG. 3 is that the bottom gate T2gl of the compensation transistor T2 is provided in the same layer as the bottom gate T3g1 of the driving transistor T3, that is, the bottom gate of the control transistor is provided in the same layer as the bottom gate T3g1 of the driving transistor T3. Because the thickness of insulation layer between the bottom gate T3g1 of the driving transistor T3 and the active layer T3a of the driving transistor T3 is smaller than the thickness of the insulation layer between the second electrode C2 of the storage capacitor Cst and the active layer T3a of the driving transistor T3, when the bottom gate T2g of the compensation transistor T2 (representing any type of the control transistor defined in the present disclosure) is provided in the same layer as the bottom gate T3g1 of driving transistor T3, the turn-on state current Ion of the compensation transistor T2 is relatively large, which can improve the driving ability of the compensation transistor T2 and improve the accuracy of signal transmission by the compensation transistor T2. The other features and technical effects of the embodiment shown in FIG. 4 are the same as those in FIG. 3, which can be referred to in the description of FIG. 3.

Continuing to refer to FIG. 3, the compensation transistor T2 further includes a top gate T2g2. The top gate T2g2 of the compensation transistor T2 is electrically connected to the bottom gate T2g1 of the compensation transistor T2 to improve the current saturation of the compensation transistor T2, resulting in a smaller and more stable change in the current change rate Δ 1% of the driving transistor T3, which improves the current stability of the driving transistor T3, because the OLED is a current driven device, the more stable the current of the driving transistor T3, the more stable the light emission, and the better the image quality. For example, the electrode where the top gate T2g2 of the compensation transistor T2 is located and the electrode where the bottom gate T2g1 of the compensation transistor T2 is located extend from the display region AA to the non-display region BD to be connected with each other in the non-display region BD, thereby achieving the electrical connection between the top gate T2g2 of the compensation transistor T2 and the bottom gate T2g1 of the compensation transistor T2.

For example, the pixel circuit further includes a switch transistor. In the first to seventh transistors T1, T2, T3, T4, T5, T6, and T7 of the pixel circuit, all transistors except for the driving transistor T3 and the control transistor (T1 and/or T2) are switch transistors. For example, the material of the active layer of the switch transistor in pixel circuit is the silicon semiconductor material. In the direction perpendicular to the main surface of the base substrate 1, the active layer of the switch transistor of the pixel circuit is located on the side of the storage capacitor Cst close to the vase substrate 1. Alternatively, in other embodiments, materials of active layers of all transistors in the pixel circuit are metal oxide semiconductor materials.

For example, referring to FIG. 1A, the first electrode T3s of the driving transistor T3 is on the side of the active layer T3a of the driving transistor T3 away from the base substrate 1. The first electrode T3s of the driving transistor T3 is electrically connected to the active layer T3a of the driving transistor T3 through the first via V1, and is electrically connected to the bottom gate T3g1 of the driving transistor T3 through the second via V2. The second electrode T3d of the driving transistor T3 is electrically connected to the active layer T3a of the driving transistor T3 through the sixth via V6; the first electrode T2s and the second electrode T2d of the compensation transistor T2 are electrically connected to the active layer T2a of the compensation transistor T2 respectively through the seventh via V7 and the eighth via V8.

For example, referring to FIG. 1A, the display substrate 10 further includes a scanning drive circuit 01 located in the non-display region BD, the scanning drive circuit 01 is, for example, a GOA (Gate Driven on Array) circuit. In FIG. 1A, the scanning drive circuit 01 is only provided in the non-display region BD on one side of the display region AA. In other embodiments, the scanning drive circuit 01 may also be provided in the non-display region BD on both sides of the display area AA, respectively. The scanning drive circuit 01 includes a switch transistor, and the scanning drive circuit 01 is configured to provide the driving scanning signals to the pixel circuit in the display region. The driving scanning signals include, for example, the first scanning signal, the second scanning signal, the first light-emitting control signal, the second light-emitting control signal, the first reset control signal Rst1, and the second reset control signal Rst2 required by the pixel circuit. For example, in the direction perpendicular to the main surface of the base substrate 1, the active layer STa of the switch transistor ST of the scanning drive circuit 01 is located on the side of the storage capacitor Cst close to the base substrate 1. For example, the material of the active layer STa of the switch transistor ST in the scanning drive circuit 01 is silicon semiconductor material; the first electrode STs and second electrode STd of the switch transistor ST of the scanning drive circuit 01 are electrically connected to the active layer STa of the switch transistor ST of the scanning drive circuit 01 respectively through the third via V3 and the fourth via V4.

For example, the display substrate 10 has a bending portion BP in the non-display region BD, for example, the display substrate 10 has a flexible substrate, and the bending portion BP can be bent to the back side of the display surface for displaying images to reduce the border of the display substrate. For example, the bending portion BP includes a driving circuit board IC and a first connection electrode E1. The first connection electrode E1 is electrically connected to the driving circuit board IC and is also electrically connected to a signal wire extending to the display region. The signal wire is electrically connected to the pixel circuit to provide a display signal to the pixel circuit. For example, the display signal includes the first power voltage VDD, common power voltage VSS, the data signal, and the like. For example, the display substrate 10 is a flexible display substrate 10, which includes a flexible organic layer and an inorganic insulation layer. The inorganic insulation layer and the flexible organic layer are stacked on the main surface of the base substrate 1, and the inorganic insulation layer is located on the side of the flexible organic layer away from the base substrate 1. The inorganic insulation layer includes a first sub inorganic layer located between the first electrode C1 and the second electrode C2 of the storage capacitor Cst, and a second sub inorganic layer located between the second electrode C2 of the storage capacitor Cst and the bottom gate T3g1 of the driving transistor T3. The display substrate 10 includes at least a fifth via V5 that penetrates the inorganic insulation layer, and the first connection electrode E1 is at least partially located in the fifth via V5. Because the inorganic insulation layer above the flexible organic layer is prone to brittle cracking and poor reliability when bent, the inorganic insulation layer above the flexible organic layer of the bending portion BP needs to be removed by opening the fifth via V5.

For example, referring to FIG. 3, the display substrate 10 further includes a first flexible layer PI1, a second flexible layer PI2, a first barrier layer Barrier1, a second barrier layer Barrier1, a third barrier layer Barrier2, a first buffer layer Buffer1, a first gate insulation layer GI1, a second gate insulation layer GI2, a first interlayer insulation layer ILD1, a second buffer layer Buffer2, a third gate insulation layer GI3, and a second interlayer insulation layer ILD2 provided on the base substrate BS. Each insulation layer achieves direct insulation of each conductive layer, and each buffer layer can isolate impurities for subsequent layers formed on the corresponding buffer layer. The materials of the first flexible layer PI1 and the second flexible layer PI2 are, for example, polyimide (PI) to make the display substrate a flexible substrate. The substrate, including polyimide (PI), contains movable fixed charges, when the gate voltage of the driving transistor T3 changes, the movable charges will move up and down with the change of the electric field formed by the gate voltage of the driving transistor T3, forming an internal electric field that changes with the gate voltage of the driving transistor T3, thereby affecting the characteristics of the driving transistor T3 and the image quality of the display substrate.

For example, the flexible organic layer includes a first flexible layer PI1 and a second flexible layer PI2; the insulation layer penetrated by the fifth via V5 includes the second barrier layer Barrier1, the third barrier layer Barrier2, the first buffer layer Buffer1, the first gate insulation layer GI1, the second gate insulation layer GI2, the first interlayer insulation layer ILD1, the second buffer layer Buffer2, the third gate insulation layer GI3, and the second interlayer insulation layer ILD2. Some or all of these layers are inorganic insulation layers. For example, the first sub inorganic layer mentioned above is the second gate insulation layer GI2, and the second sub inorganic layer is the first interlayer insulation layer ILD1.

Referring to FIG. 3, the first electrode T3s and second electrode T3d of the driving transistor T3, the first electrode T2s and second electrode T2d of the compensation transistor T2, the first electrode STs and second electrode STd of the switch transistor ST of the scanning drive circuit 01, and the first connection electrode E1 are all arranged in the same layer, for example, are all located in the first conductive layer SD1. The first conductive layer SD1 is located on the side of the active layer T3a of the driving transistor T3 away from the base substrate 1, for example, located on the side of the top gate T3g2 of the driving transistor T3 away from the base substrate 1.

FIG. 5 is a partial cross-sectional schematic diagram of a pixel circuit of another display substrate provided by at least one embodiment of the present disclosure. In FIG. 5, the compensation transistor T2 is used as an example of the control transistor. The control transistor may also be the first reset transistor T1. Of course, the control transistor is not limited to including the compensation transistor T2 and the first reset transistor T1. In other embodiments, all transistors of the pixel circuit except for the driving transistor T3 can be the control transistor, that is, the material of the active layer thereof may all be silicon semiconductor material.

Referring to FIG. 5, the difference between the embodiment shown in FIG. 5 and the embodiment shown in FIG. 3 is that the orthographic projection of the storage capacitor Cst on the main surface of the base substrate 1 does not overlap with the orthographic projection of the driving transistor T3 on the main surface of the base substrate 1 and the orthographic projection of the control transistor on the main surface of the base substrate 1. In this way, it can reduce the complexity of the layer stacking below the driving transistor T3 (Oxide TFT), thereby improving the CD uniformity of the top gate T3g2 of the driving transistor T3, and improving the uniformity of the device characteristics of the driving transistor T3, and the driving transistor T3 can play a better driving effect. The other features and technical effects of the embodiment shown in FIG. 5 are the same as those in FIG. 3, which can be referred to in the description of FIG. 3.

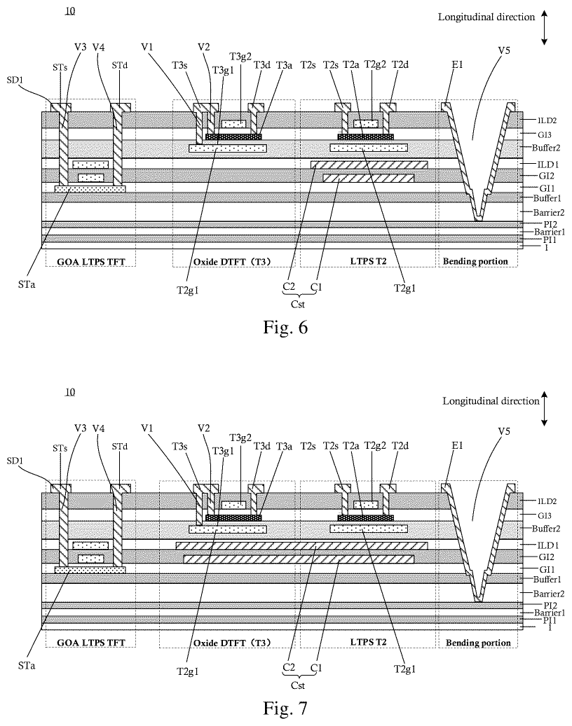

FIG. 6 is a partial cross-sectional schematic diagram of a pixel circuit of another display substrate provided by at least one embodiment of the present disclosure. In FIG. 6, the compensation transistor T2 is still used as an example of the control transistor. The control transistor may also be the first reset transistor T1. Of course, the control transistor is not limited to including the compensation transistor T2 and the first reset transistor T1. In other embodiments, all transistors of the pixel circuit except for the driving transistor T3 can be the control transistor, that is, the material of the active layer thereof can be silicon semiconductor material.

The embodiment shown in FIG. 6 differs from the embodiment shown in FIG. 4 as follows. Referring to FIG. 6, the orthographic projection of the storage capacitor Cst on the main surface of the base substrate 1 at least partially overlaps with the orthographic projection of the control transistor (such as the compensation transistor T2) on the main surface of the base substrate 1. Of course, the control transistor here may also be the first reset transistor T1, that is, the orthographic projection of the storage capacitor Cst on the main surface of the base substrate 1 at least partially overlaps with the orthographic projection of the first reset transistor T1 on the main surface of the base substrate 1. Compared to being provided below the driving transistor T3 (Oxide TFT), the scheme shown in FIG. 6 can reduce the complexity of the layer stacking below the driving transistor T3 (Oxide TFT), thereby improving the CD uniformity of the top gate T3g2 of the driving transistor T3, and improving the uniformity of the device characteristics of the driving transistor T3, and the driving transistor T3 can play a better driving effect. Due to the crucial impact of the performance of the driving transistor T3 on the display effect, it is crucial to ensure that the performance of the driving transistor T3 is not affected by the complex layer below. Moreover, in the display substrate, the connection wires close to the driving transistor T3 are denser and more complex. Providing the first electrode and the second electrode of the storage capacitor Cst below the control transistor (i.e. the orthogonal projections of the two are overlapped) is more conducive to pixel design, and limited space can be used to reasonably layout various electrodes and lines, thereby improving the PPI of the display substrate 10.

Referring to FIG. 6, for example, the active layer T2a of the compensation transistor T2 and the active layer T3a of the driving transistor T3 are in the same layer; the compensation transistor T2 includes a bottom gate T2g1, and the bottom gate T2g1 of the compensation transistor T2 and the bottom gate T3g1 of the driving transistor T3 are in the same layer to make reasonable use of the existing layer below the compensation transistor T2 to set the bottom gate T2g1 of the compensation transistor T2 and the first electrode C1 and the second electrode C2 of the storage capacitor Cst, thereby simplifying the structure and manufacture process of the display substrate 10.

Referring to FIG. 6, for example, the orthographic projection of the first electrode C1 of the storage capacitor Cst on the main surface of the base substrate 1 is within the range of the orthographic projection of the second electrode C2 of the storage capacitor Cst on the main surface of the base substrate 1, and the orthographic projection of the bottom gate T2g1 of the compensation transistor T2 on the main surface of the base substrate 1 is within the range of the orthographic projection of the first electrode C1 of the storage capacitor Cst on the main surface of the base substrate 1. As above, it is beneficial to ensure the etching uniformity or CD uniformity of the first electrode C1 and second electrode C2 of the storage capacitor Cst and the bottom gate T2g1 of the compensation transistor T2.

For example, the gate electrode of the compensation transistor T2 further includes a top gate T2g2. In the direction perpendicular to the main surface of the base substrate 1, the top gate T2g2 of the compensation transistor T2 is located on the side of the active layer T2a of the compensation transistor T2 away from the base substrate 1; the orthographic projection of the top gate T2g2 of the compensation transistor T2 on the main surface of the base substrate 1 is within the range of the orthographic projection of the bottom gate T2g1 of the compensation transistor T2 on the main surface of the base substrate 1. As above, it is beneficial to ensure the etching uniformity or CD uniformity of the top gate T2g2 of the compensation transistor T2, and the Tapper angle of the top gate T2g2, thereby facilitating the covering reliability of the second interlayer insulation layer ILD2 and ensuring the insulation effect thereof.

The other features and technical effects of the embodiment shown in FIG. 6 are the same as those in FIG. 4, which can be referred to in the description of FIG. 4.

FIG. 7 is a partial cross-sectional schematic diagram of a pixel circuit of another display substrate provided by at least one embodiment of the present disclosure. In FIG. 7, the compensation transistor T2 is still used as an example of the control transistor, the control transistor may also be the first reset transistor T1. Of course, the control transistor is not limited to including the compensation transistor T2 and the first reset transistor T1. In other embodiments, all transistors of the pixel circuit except for the driving transistor T3 can be the control transistor, that is, the material of the active layer thereof can be silicon semiconductor material.

The embodiment shown in FIG. 7 differs from the embodiment shown in FIG. 6 as follows. Referring to FIG. 7, the orthographic projection of the storage capacitor Cst on the main surface of the base substrate 1 at least partially overlaps with the orthographic projection of the driving transistor T3 on the main surface of the base substrate 1 and the orthographic projection of at least one control transistor on the main surface of the base substrate 1. For example, the orthographic projection of the storage capacitor Cst on the main surface of the base substrate 1 at least partially overlaps with the orthographic projection of the driving transistor T3 on the main surface of the base substrate 1 and the orthographic projection of the compensation transistor T2 on the main surface of the base substrate 1. Alternatively, the orthographic projection of the storage capacitor Cst on the main surface of the base substrate 1 at least partially overlaps with the orthographic projection of the driving transistor T3 on the main surface of the base substrate 1 and the orthographic projection of the first reset transistor T1 on the main surface of the base substrate 1. Alternatively, the orthographic projection of the storage capacitor Cst on the main surface of the base substrate 1, the orthographic projection of the driving transistor T3 on the main surface of the base substrate 1, the orthographic projection of the first reset transistor T1 on the main surface of the base substrate 1, and the orthographic projection of the compensation transistor T2 on the main surface of substrate lare all at least partially overlapped with each other. In this way, without affecting the pixel design space and the PPI of the display substrate 10, the size of the pixel capacitance can be increased by increasing the area of the pixel capacitor, thereby improving the compensation ability of the pixel capacitance to the pixel.

Referring to FIG. 7, for example, the active layer T2a of the compensation transistor T2 and the active layer T3a of the driving transistor T3 are provide in the same layer; the bottom gate T2g1 of the compensation transistor T2 and the bottom gate T3g1 of the driving transistor T3 are provided in the same layer, to reasonably utilize the existing layer below the driving transistor T3 and the compensation transistor T2 to form both bottom gates, thereby simplifying the structure and manufacture process of the display substrate 10.

Referring to FIG. 7, for example, the orthographic projection of the first electrode C1 of the storage capacitor Cst on the main surface of the base substrate 1 is within the range of the orthographic projection of the second electrode C2 of the storage capacitor Cst on the main surface of the base substrate 1, the orthographic projection of the bottom gate T3g1 of the driving transistor T3 on the main surface of the base substrate 1 and the orthographic projection of the bottom gate of the control transistor on the main surface of the base substrate 1 are both within range of the orthographic projection of the first electrode C1 of the storage capacitor Cst on the main surface of the base substrate 1. As above, this can ensure the etching uniformity or CD uniformity of the storage capacitor Cst and the bottom gate T3g1 of the driving transistor T3.

Referring to FIG. 7, for example, the orthographic projection of the interval between the driving transistor T3 and the compensation transistor T2 on the main surface of the base substrate 1 is also within the range of the orthographic projection of the storage capacitor Cst on the main surface of the base substrate 1, that is, within the range of the orthographic projection of the first electrode C1 of the storage capacitor Cst on the main surface of the base substrate 1 and within the range of the orthographic projection of the second electrode C2 of the storage capacitor Cst on the main surface of the base substrate 1.

The other features and technical effects of the embodiment shown in FIG. 7 are the same as those in FIG. 6, which can be referred to in the description of FIG. 6.

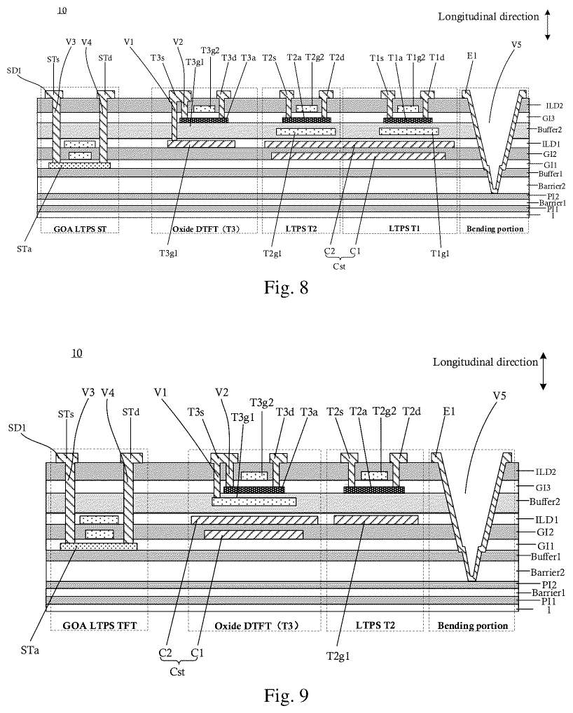

FIG. 8 is a partial cross-sectional schematic diagram of a pixel circuit of another display substrate provided by at least one embodiment of the present disclosure. In FIG. 8, the compensation transistor T2 and the first reset transistor T1 are used as an example of the control transistor. Of course, the control transistor is not limited to including the compensation transistor T2 and the first reset transistor T1. In other embodiments, all transistors of the pixel circuit except for the driving transistor T3 can be the control transistor, that is, the material of the active layer thereof can be silicon semiconductor material.

The embodiment shown in FIG. 8 differs from the embodiment shown in FIG. 7 as follows. Referring to FIG. 8, for example, the orthographic projection of the storage capacitor Cst on the main surface of the base substrate 1 does not overlap with the orthographic projection of the driving transistor T3 on the main surface of the base substrate 1, and at least partially overlaps with the orthographic projections of a plurality of control transistors on the main surface of the base substrate 1. For example, the orthographic projection of compensation transistor T2 on the main surface of the base substrate 1 at least partially overlaps with the orthographic projection of the first reset transistor T1 on the main surface of the base substrate 1. In this way, on the one hand, on the basis of not affecting the pixel design space and the PPI of the display substrate 10, it is possible to further increase the area of the storage capacitor to increase the storage capacitance value, thereby improving the compensation ability of the pixel capacitance to the pixel; on the other hand, it can reduce the complexity of the layer stacking below the driving transistor T3 (Oxide TFT). In the display substrate, the connection wires close to the driving transistor T3 are denser and more complex. Providing the first electrode and the second electrode of the storage capacitor Cst under the plurality if control transistors is more conducive to pixel design, and limited space can be used to reasonably layout each electrode and line, thereby improving the PPI of the display substrate 10.

Referring to FIG. 8, for example, the active layer T2a of the compensation transistor T2 and the active layer Tla of the first reset transistor T1 are both in the same layer as the active layer T3a of the driving transistor T3, and the materials thereof are the same, which can be formed through single one patterning process. The bottom gate T2g1 of the compensation transistor T2 and the bottom gate T1g1 of the first reset transistor T1 are both in the same layer as the bottom gate T3g1 of the driving transistor T3. That is, the active layer of the control transistor is in the same layer as the active layer T3a of the driving transistor T3; each control transistor includes a bottom gate, and bottom gates of the plurality of control transistors are in the same layer as the bottom gate T3g1 of the driving transistor T3.

Referring to FIG. 8, for example, the orthographic projection of the first electrode C1 of the storage capacitor Cst on the main surface of the base substrate 1 is within the range of the orthographic projection of the second electrode C2 of the storage capacitor Cst on the main surface of the base substrate 1, and the orthographic projections of bottom gates of the plurality of control transistors (such as the bottom gate T2g1 of the compensation transistor T2 and the bottom gate T1g1 of the first reset transistor T1) on the main surface of the base substrate 1 is within the range of the orthographic projection of the first electrode C1 of the storage capacitor Cst on the main surface of the base substrate 1. For example, the orthographic projection of the interval between the plurality of control transistors on the main surface of the base substrate 1 is within the range of the orthographic projection of the storage capacitor Cst on the main surface of the base substrate 1. For example, in FIG. 8, the orthographic projection of the interval between the compensation transistor T2 and the first reset transistor T1 on the main surface of the base substrate 1 is within the range of the orthographic projection of the storage capacitor Cst on the main surface of the base substrate 1. As above, this can ensure the etching uniformity or CD uniformity of the storage capacitor Cst and the bottom gates of the plurality of control transistors. Furthermore, for example, the orthographic projection of the top gate of each control transistor (such as the top gate T2g2 of the compensation transistor T2 and the top gate T1g2 of the first reset transistor T1) on the main surface of the base substrate 1 is within the range of the orthographic projection of the bottom gate of the each control transistor (such as the bottom gate T2g1 of the compensation transistor T2 and the bottom gate T1g1 of the first reset transistor T1) on the main surface of the base substrate 1.

Referring to FIG. 8, for example, the bottom gate T3g1 of the driving transistor T3 and the second electrode C2 of the storage capacitor Cst are in the same layer, and located between the bottom gates of the plurality of control transistors and the first electrode C1 of the storage capacitor Cst, to utilize the sufficient space in the conductive layer where the second electrode C2 of the storage capacitor Cst is located to set the bottom gate T3g1 of the driving transistor T3, thereby reducing the electrode density of the conductive layer where the bottom gate T2g1 of the compensation transistor T2 and the bottom gate T1g1 of the first reset transistor T1 are located, preventing short circuits and signal interference between electrodes that are too close, and reasonably arranging the structure of the pixel circuit.

The other features and technical effects of the embodiment shown in FIG. 8 are the same as those in FIG. 7, which can be referred to in the description of FIG. 7.

FIG. 9 is a partial cross-sectional schematic diagram of a pixel circuit of another display substrate provided by at least one embodiment of the present disclosure. In FIG. 9, the compensation transistor T2 and the first reset transistor T1 are used as an example of the control transistor. Of course, the control transistor is not limited to including the compensation transistor T2 and the first reset transistor T1. In other embodiments, all transistors of the pixel circuit except for the driving transistor T3 can be the control transistor, that is, the material of the active layer thereof can be silicon semiconductor material.

The embodiment shown in FIG. 9 differs from the embodiment shown in FIG. 8 as follows. Referring to FIG. 9, for example, the bottom gate T3g1 of the driving transistor T3 is in the same layer as the second electrode C2 of the storage capacitor Cst, and the control transistor does not include a gate located between the layer where the second electrode C2 of the storage capacitor Cst is located and the active layer of the control transistor. In addition, for the driving transistor T3, in order to enhance its driving performance, a double gate structure is retained, and the bottom gate T3g1 of the driving transistor T3 is in the same layer as the second electrode C2 of the storage capacitor Cst. In this way, it can eliminate the conductive layer below the bottom gate of the control transistor, that is, the control transistor is a single gate transistor. On the one hand, it can reduce one manufacture process of the conductive layer where the bottom gate is located, and reduce the production cost of the display substrate 10; on the other hand, by eliminating the bottom gate below the control transistor, the metal lines in the pixel region can be reduced, thereby improving the PPI of the display substrate 10.

The other features and technical effects of the embodiment shown in FIG. 9 are the same as those in FIG. 8, which can be referred to in the description of FIG. 8.

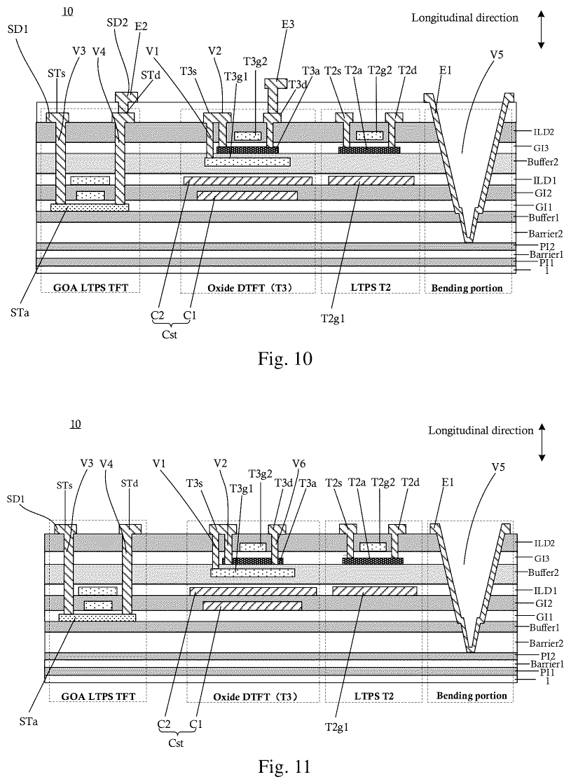

FIG. 10 is a partial cross-sectional schematic diagram of a pixel circuit of another display substrate provided by at least one embodiment of the present disclosure. The embodiment shown in FIG. 10 differs from the embodiment shown in FIG. 3 as follows. Referring to FIG. 10, for example, the display substrate 10 further includes a second conductive layer SD2, which is on the side of the first conductive layer SD1 away from the base substrate 1. The first connection electrode E1 may be located in the second conductive layer SD2. For example, the sub-pixel further includes a second connection electrode E2 electrically connected to the second electrode STd of the switch transistor of the scanning drive circuit 01, and a third connection electrode E3 electrically connected to the second electrode T3d of the driving transistor T3. The second connection electrode E2 and the third connection electrode E3 are both located in the second conductive layer SD2.

The other features and technical effects of the embodiment shown in FIG. 10 are the same as those in FIG. 3, which can be referred to in the description of FIG. 3.

FIG. 11 is a partial cross-sectional schematic diagram of a pixel circuit of another display substrate provided by at least one embodiment of the present disclosure. The embodiment shown in FIG. 11 differs from the embodiment shown in FIG. 10 as follows. In FIG. 11, the second via V2 passes through the active layer T3a of the driving transistor T3 in the direction perpendicular to the main surface of the base substrate 1, and the sixth via V6 passes through the active layer T3a of the driving transistor T3 in the direction perpendicular to the main surface of the base substrate 1. The first electrode T3s of the driving transistor T3 includes a first hole inner portion PIV1 in the second via V2, and the second electrode T3d of the driving transistor T3 includes a second hole inner portion PIV2 in the sixth via V6. The side surface of the first hole inner portion PIV1 contacts the active layer T3a of the driving transistor T3 to be electrically connected to the active layer T3a of the driving transistor T3, while the side surface of the second hole inner portion PIV2 contacts the active layer T3a of the driving transistor T3 to be electrically connected to the active layer T3a of the driving transistor T3; the plane where the side surface of the first hole inner portion PIV1 is located intersects with the main surface of the base substrate 1, while the plane where the side surface of the second hole inner portion PIV2 is located intersects with the main surface of the base substrate 1. In FIG. 11, a side contact connection method is used to electrically connect the first electrode T3s of the driving transistor T3 and the second electrode T3d of the driving transistor T3 to the active layer T3a of the driving transistor T3, respectively. While in FIG. 10, a bottom contact connection method is used to electrically connect the first electrode T3s of the driving transistor T3 and the second electrode T3d of the driving transistor T3 to the active layer T3a of the driving transistor T3.

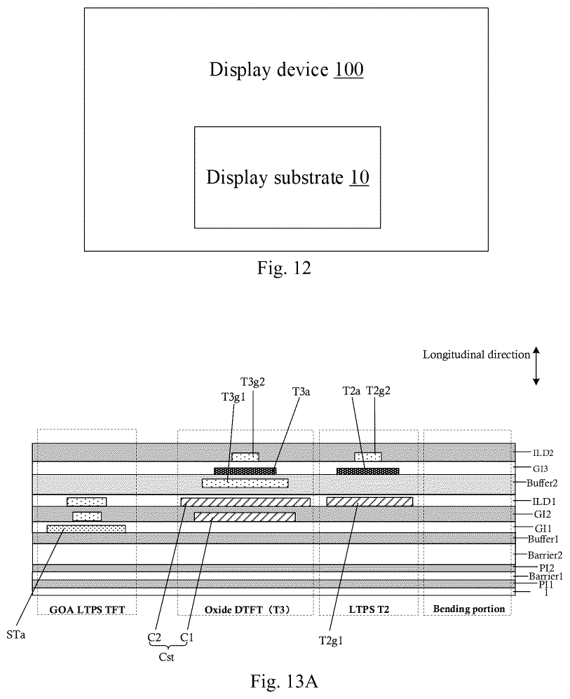

FIG. 12 is a schematic diagram of a display apparatus provided by an embodiment of the present disclosure. Referring to FIG. 12, at least one embodiment of the present disclosure further provides a display apparatus 100, the display apparatus 100 includes any one of the display substrates 10 provided by the embodiments of the present disclosure. The display apparatus, for example, can be a display panel, or any product or component with display functions, such as a monitor, OLED panel, OLED TV, e-paper, mobile phone, tablet, laptop, digital photo frame, navigation device, etc. Of course, the display apparatus provided by the embodiments of the present disclosure is not limited to the types listed above.

Correspondingly, the display panel and display apparatus provided by the embodiments of the present disclosure have the technical effects of the pixel circuit and display substrate provided by the embodiments of the present disclosure.

At least one embodiment of the present disclosure further provides a manufacture method of a display substrate, the manufacture method includes: forming a sub-pixel, including forming a pixel circuit of the sub-pixel includes, in which the pixel circuit includes a light-emitting device and a driving transistor T3, the driving transistor T3 is configured to control a magnitude of a driving current flowing through the light-emitting device according to a data signal; and forming a data transistor T4 of the pixel circuit, in which the data transistor T4 is configured to write the data signal into a first electrode of the driving transistor T3 in response to a data driving signal; a material of an active layer of the driving transistor T3 includes a metal oxide semiconductor material, and a material of an active layer of the data transistor T4 includes a silicon semiconductor material.

For example, the manufacture method of the display substrate 10 includes providing a base substrate 1 and forming various structures of the pixel circuit on the main surface of the base substrate 1. The manufacture method of the display substrate includes forming a first via V1, a second via V2, a third via V3, a fourth via V4, and a fifth via V5 through single one patterning process.

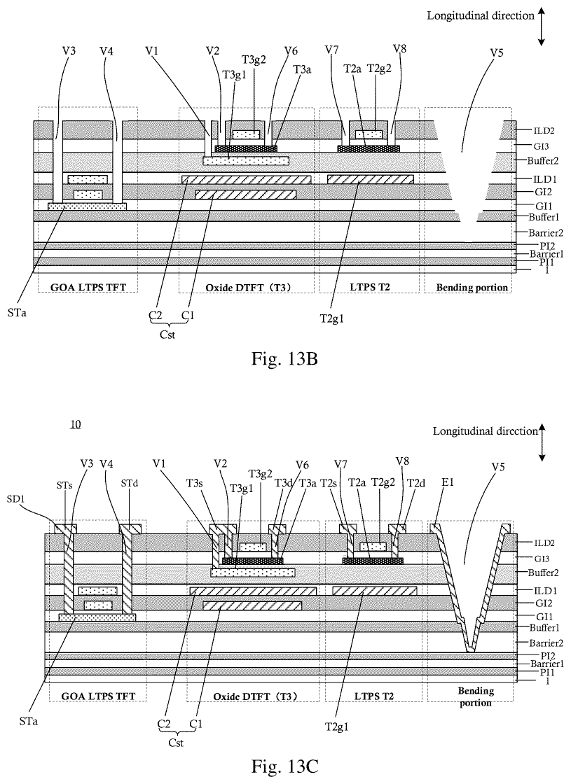

FIG. 13A to FIG. 13C are schematic diagrams of the manufacture method of a display substrate provided by an embodiment of the present disclosure. Taking the manufacture of the display substrate 10 shown in FIG. 3 as an example to illustrate.

Referring to FIG. 13A, providing the base substrate BS, and forming a first flexible layer PI1, a first barrier layer Barrier1, a second flexible layer PI2, a second barrier layer Barrier2, a first buffer layer Buffer1, an active layer T3a of the driving transistor T3 and an active layer T2a of the compensation transistor T2, a first gate insulation layer GI1, a first electrode C1 of the storage capacitor Cst, a second gate insulation layer GI2, the first electrode C2 of the storage capacitor Cst and the bottom gate T2g1 of the compensation transistor T2, the first interlayer insulation layer ILD1 and the second buffer layer Buffer2, the bottom gate T3g1 of the driving transistor T3, the top gate T3g2 of the driving transistor T3, and the top gate T2g2 of the compensation transistor T2 on the base substrate BS.

Then, referring to FIG. 13B, the first via V1, the second via V2, the third via V3, the fourth through via V4, the fifth via V5, the sixth via V6, the seventh via V7, and the eighth via V8 are formed through single one patterning process.

For example, the manufacture method further includes etching the surface of the active layer T3a of the driving transistor T3 exposed by the second via V2 and the sixth via V6 after forming the above vias, to remove the oxide layer on the surface of the active layer T3a of the driving transistor T3 exposed by the second via V2 and the sixth via V6, thereby reducing the contact resistance of the exposed surface.

Then, referring to FIG. 13C, various electrodes in the second conductive layer SD2 are formed through single one patterning process, the various electrodes include the first electrode T3s and second electrode T3d of the driving transistor T3, the first electrode T2s and second electrode T2d of the compensation transistor T2, the first electrode STs and second electrode STd of the switch transistor ST of the scanning drive circuit 01, and the first connection electrode E1. The first electrode T3s of the driving transistor T3 is electrically connected to the active layer T3a of the driving transistor T3 through the first via V1, and is electrically connected to the bottom gate T3g1 of the driving transistor T3 through the second via V2. The second electrode T3d of the driving transistor T3 is electrically connected to the active layer T3a of the driving transistor T3 through the sixth via V6. The first electrode T2s and second electrode T2d of the compensation transistor T2 are electrically connected to the active layer T2a of the compensation transistor T2 respectively through the seventh via V7 and the eighth via V8; the first electrode STs and second electrode STd of the switch transistor ST of the scanning drive circuit 01 are electrically connected to the active layer STa of the switch transistor ST of the scanning drive circuit 01 respectively through the third via V3 and the fourth via V4; the first connection electrode E1 is electrically connected to the driving circuit board IC, and is electrically connected to the signal wire extending to the display region. The first connection electrode E1 is at least partially located in the fifth via V5.

The display substrate provided by other embodiments can also be made by similar methods.

What have been described above are only specific implementations of the present disclosure, the protection scope of the present disclosure is not limited thereto. The protection scope of the present disclosure should be based on the protection scope of the claims.

1. A display substrate, comprising a sub-pixel, wherein the sub-pixel comprises a pixel circuit, the pixel circuit comprises a light-emitting device and a driving transistor, the driving transistor is configured to control a magnitude of a driving current flowing through the light-emitting device according to a data signal;
the pixel circuit further comprises a data transistor, the data transistor is configured to write the data signal into a first electrode of the driving transistor in response to a data driving signal;
a material of an active layer of the driving transistor is a metal oxide semiconductor material, and a material of an active layer of the data transistor is a silicon semiconductor material.

2. The display substrate according to claim 1, wherein the display substrate further comprises a base substrate, and the pixel circuit is on a main surface of the base substrate;
the pixel circuit further comprises a storage capacitor, a first electrode of the storage capacitor is electrically connected to a gate electrode of the driving transistor, and a second electrode of the storage capacitor is electrically connected to a first power voltage terminal to receive a first power voltage;
the gate electrode of the driving transistor comprises a bottom gate, in a direction perpendicular to the main surface of the base substrate, the bottom gate is on a side of the active layer of the driving transistor close to the base substrate;
the first electrode of the storage capacitor, the second electrode of the storage capacitor, and the bottom gate of the driving transistor are in different layers from each other, and both the first electrode of the storage capacitor and the second electrode of the storage capacitor are on a side of the active layer of the driving transistor close to the base substrate.

3. The display substrate according to claim 2, wherein the pixel circuit further comprises a control transistor, a first electrode of the control transistor is electrically connected to the gate electrode of the driving transistor, and a material of an active layer of the control transistor is the metal oxide semiconductor material;
the pixel circuit comprises a first reset transistor, the first reset transistor is configured to write a first reset signal to the gate electrode of the driving transistor under a control of a first reset control signal;
the pixel circuit further comprises a compensation transistor, the compensation transistor is configured to compensate for a signal applied to the gate electrode of the driving transistor in response to a compensation scanning signal and the data signal;
the control transistor comprises at least one of the first reset transistor and the compensation transistor, and a material of an active layer of at least one of the first reset transistor and the compensation transistor is the metal oxide semiconductor material.

4. The display substrate according to claim 3, wherein the gate electrode of the driving transistor further comprises a top gate, in the direction perpendicular to the main surface of the base substrate, the top gate is on a side of the active layer of the driving transistor away from the base substrate;
the first electrode of the storage capacitor is electrically connected to the top gate of the driving transistor, and the second electrode of the storage capacitor is electrically connected to the first power voltage terminal.

5. The display substrate according to claim 3, wherein an orthographic projection of the storage capacitor on the main surface of the base substrate at least partially overlaps with an orthographic projection of the driving transistor on the main surface of the base substrate.

6. The display substrate according to claim 5, wherein the first electrode of the storage capacitor is on a side of the second electrode of the storage capacitor close to the base substrate, and an orthographic projection of the first electrode of the storage capacitor on the main surface of the base substrate is within a range of an orthographic projection of the second electrode of the storage capacitor on the main surface of the base substrate, an orthographic projection of the bottom gate of the driving transistor on the main surface of the base substrate is within a range of an orthographic projection of the first electrode of the storage capacitor on the main surface of the base substrate.

7. The display substrate according to claim 6, wherein the gate electrode of the driving transistor further comprises a top gate, in the direction perpendicular to the main surface of the base substrate, the top gate of the driving transistor is on a side of the active layer of the driving transistor away from the base substrate;
an orthographic projection of the top gate of the driving transistor on the main surface of the base substrate is within a range of the orthographic projection of the bottom gate of the driving transistor on the main surface of the base substrate.

8. The display substrate according to claim 3, wherein the active layer of the control transistor and the active layer of the driving transistor are in a same layer;
a gate electrode of the control transistor comprises a bottom gate, the bottom gate of the control transistor and the second electrode of the storage capacitor are in a same layer, or,
the bottom gate of the control transistor and the bottom gate of the driving transistor are in a same layer.

9. The display substrate according to claim 3, wherein an orthographic projection of the storage capacitor on the main surface of the base substrate does not overlap with an orthographic projection of the driving transistor on the main surface of the base substrate and does not overlap with an orthographic projection of the control transistor on the main surface of the base substrate.

10. The display substrate according to claim 3, wherein an orthographic projection of the storage capacitor on the main surface of the base substrate at least partially overlaps with an orthographic projection of the control transistor on the main surface of the base substrate.

11. The display substrate according to claim 10, wherein the active layer of the control transistor and the active layer of the driving transistor are in a same layer;
a gate electrode of the control transistor comprises a bottom gate, and the bottom gate of the control transistor and the bottom gate of the driving transistor are in a same layer;
an orthographic projection of the first electrode of the storage capacitor on the main surface of the base substrate is within a range of an orthographic projection of the second electrode of the storage capacitor on the main surface of the base substrate, and an orthographic projection of the bottom gate of the control transistor on the main surface of the base substrate is within a range of the orthographic projection of the first electrode of the storage capacitor on the main surface of the base substrate.

12. The display substrate according to claim 11, wherein the gate electrode of the control transistor further comprises a top gate, in the direction perpendicular to the main surface of the base substrate, the top gate of the control transistor is on a side of the active layer of the control transistor away from the base substrate;
an orthographic projection of the top gate of the control transistor on the main surface of the base substrate is within a range of an orthographic projection of the bottom gate of the control transistor on the main surface of the base substrate.

13. The display substrate according to claim 3, wherein an orthographic projection of the storage capacitor on the main surface of the base substrate at least partially overlaps with an orthographic projection of the driving transistor on the main surface of the base substrate and at least partially overlaps with an orthographic projection of at least one control transistor on the main surface of the base substrate.

14. The display substrate according to claim 13, wherein the active layer of the control transistor and the active layer of the driving transistor are in a same layer;
the control transistor comprises a bottom gate, and the bottom gate of the control transistor and the bottom gate of the driving transistor are in a same layer;
an orthographic projection of the first electrode of the storage capacitor on the main surface of the base substrate is within a range of an orthographic projection of the second electrode of the storage capacitor on the main surface of the base substrate, and an orthographic projection of the bottom gate of the driving transistor on the main surface of the base substrate and an orthographic projection of the bottom gate of the control transistor on the main surface of the base substrate are both within a range of the orthographic projection of the first electrode of the storage capacitor on the main surface of the base substrate.

15. The display substrate according to claim 13, wherein an orthographic projection of an interval between the driving transistor and the control transistor on the main surface of the base substrate is within a range of the orthographic projection of the storage capacitor on the main surface of the base substrate.

16. The display substrate according to claim 3, wherein an orthographic projection of the storage capacitor on the main surface of the base substrate does not overlap with an orthographic projection of the driving transistor on the main surface of the base substrate, and at least partially overlaps with orthographic projections of a plurality of the control transistors on the main surface of the base substrate.

17. The display substrate according to claim 16, wherein all of active layers of the plurality of control transistors and the active layer of the driving transistor are in a same layer;
each of the plurality of control transistors comprises a bottom gate, and the bottom gates of the plurality of control transistors and the bottom gate of the driving transistor are in a same layer;
an orthographic projection of the first electrode of the storage capacitor on the main surface of the substrate is within a range of an orthographic projection of the second electrode of the storage capacitor on the main surface of the substrate, and orthographic projections of the bottom gates of the plurality of control transistors on the main surface of the substrate are all within a range of the orthographic projection of the first electrode of the storage capacitor on the main surface of the substrate.

18. The display substrate according to claim 2, wherein the second electrode of the storage capacitor is between the first electrode of the storage capacitor and the bottom gate of the driving transistor.

19. The display substrate according to claim 10, wherein the bottom gate of the driving transistor and the second electrode of the storage capacitor are in a same layer, and is between the bottom gates of a plurality of the control transistors and the first electrode of the storage capacitor.

20-24. (canceled)

25. A display apparatus, comprising the display substrate according to claim 1.

26-27. (canceled)
